(19) United States
(12) Patent Application Publication
(10) Pub. No.: US 2009/0246912 A1
(43) Pub. Date: Oct. 1, 2009

(54) METHOD OF PRODUCING SEMICONDUCTOR PACKAGES

(76) Inventor: Jun Ueda, Yoshino-gun (JP)

Correspondence Address: BIRCH STEWART KOLASCH & BIRCH, PO BOX 747, FALLS CHURCH, VA, 22040-0747, US

(21) Appl. No.: 12/415,493

(22) Filed: Mar. 31, 2009

(30) Foreign Application Priority Data
Apr. 1, 2008 (JP) 2008-094943

(51) Int. Cl. H01L 21/50

(52) U.S. Cl. 438/113; 257/E21.499; 438/123; 438/124

(57) ABSTRACT

Semiconductor chips are fixed to one of two opposite surfaces of a leadframe, and the leadframe is electrically connected to each semiconductor chip with wires. After having applied water-soluble masking ink to the other surface of the leadframe, a sealed structure is molded. Then, when the sealed structure is cut with cutting water into individual semiconductor packages, burrs of the mold resin formed on the other surface side of the leadframe are removed by the cutting water while the masking ink on the other surface of the leadframe is dissolved and removed by the cutting water.

### TECHNICAL FIELD

This invention relates to a method of producing semiconductor packages of, for example, QFN type.

### BACKGROUND ART

In recent years there has been a demand for miniaturization of semiconductor packages for the necessity to mount semiconductor parts in electronic equipment in high density. As such a semiconductor package meeting the demand, QFNs (Quad Flatpack Non-leaded packages) have been used.

The QFN package is a semiconductor package from which outer leads, which in a conventional semiconductor package protrude laterally outwards, have been eliminated. Instead, an external electrode for electrical connection with a substrate is provided at the underside of the QFN package.

Generally, semiconductor packages have a leadframe sealed with a mold resin to secure air tightness. In QFN-type semiconductor packages, to prevent resin burrs from occurring, the molding process is performed typically with an adhesive-coated masking sheet attached to the exposed leadframe. For example, conventionally there has been proposed a QFN package in which an adhesive tape is stuck on an exposed surface of the leadframe to seal (refer to JP 2004-22801A).

However, the conventional method of producing the semiconductor package requires a step of sticking adhesive tape on an exposed surface of the leadframe and a step of removing the adhesive tape, resulting in increase of man-hours. Also, the method involves the material cost of the adhesive tape, and the removed adhesive tape has become the industrial waste.

It is most desirable from the viewpoint of reducing costs and man-hours to apply the adhesive tape to the leadframe before the leadframe starts to be subjected to the package production process steps. However, if the leadframe attached with the adhesive tape is subjected to a die bonding process and a wire bonding process, defectiveness of the wire bonding may be caused by the deformation of the tape and absorption of the supersonic wave. This may invite decreased process yields.

In order to avoid such problems, there has been suggested performing a process to attach the adhesive tape after completion of the wire bonding process. Also, jigs therefor have been proposed. However, according to this method, in order to protect a semiconductor chip and wires on a lead frame, it is indispensable to make exclusive jigs depending on the package size. This may increase the initial costs of the production facility, and inevitably lead to the increase in costs of the final product.

In addition, packages having resin burrs, which is formed to a very small amount on a lower part of the leadframe in spite of the presence of the adhesive tape stuck beforehand during a transfer molding process, have conventionally been eliminated and disposed of as defective packages at the final visual inspection process.

### SUMMARY OF THE INVENTION

Thus, an object of the present invention is to provide a method of producing a semiconductor package which can prevent resin burrs from occurring, as with the conventional method using adhesive tape, which can dispense with adhesive tapes involving the conventionally required processes of attaching and removing the adhesive tape to thereby reduce the man-hours and the material costs, and which can salvage semiconductor packages, conventionally determined as defective at the appearance inspection, to thereby improve the yields and reduce the costs.

In order to achieve the object, a method of producing semiconductor packages according to the present invention comprises:

a die bonding process of fixing a plurality of semiconductor chips on one of two opposite surfaces of a leadframe;

a wire bonding process of electrically connecting each of the semiconductor chips to the leadframe by wires;

an application process of applying a water-soluble masking ink to the other surface of the leadframe;

a molding process of sealing the leadframe and all of the semiconductor chips with a molding resin in such a manner that the masking ink on the other surface of the leadframe is exposed, to thereby form a sealed structure;

a process of cutting the sealed structure into individual semiconductor packages by using cutting water and dissolving the masking ink on the other surface of the leadframe by the cutting water to remove the masking ink while removing, by the cutting water, burrs of the mold resin which are formed on the other surface side of the leadframe.

The production method of this invention can prevent burrs of the mold resin, like the conventional method using adhesive tape, by applying water-soluble masking ink to the other surface of the leadframe.

Also, when the sealed structure is cut with the cutting water into individual semiconductor packages, the masking ink at the other surface of the leadframe is dissolved and removed with the cutting water. Thus, the conventionally required processes of attaching and removing the adhesive tape are no more necessary.

Also, when the sealed structure is cut with cutting water into individual semiconductor packages, burrs of the mold resin formed on the other surface side of the leadframe are removed by the cutting-water at the same time.

Thus, according to the present invention, resin burrs are prevented from occurring, as with the conventional method using adhesive tapes. Also, the conventionally required processes of attaching and removing the adhesive tapes are dispensed with, so that the man-hours and the material costs can be reduced. Also, semiconductor packages with resin burrs, which have conventionally been determined as defective at the appearance inspection, can be salvaged, so that improvement of the yields and reduction of the costs are expected.

In one embodiment, the application process comprises spraying the masking ink directly to the other surface of the leadframe by ink-jet method.

In this embodiment, because the masking ink is sprayed directly onto the other surface of the leadframe by the ink-jet method during the application process, the masking ink can be applied easily.

### ADVANTAGEOUS EFFECTS OF THE INVENTION

Because the method of semiconductor packages of this invention comprises the application process of applying the water-soluble masking ink to the other surface of the leadframe, and the process of cutting the sealed structure into individual semiconductor packages by using cutting water and dissolving the masking ink on the other surface of the leadframe by the cutting water to remove the masking ink while removing, by the cutting water, burrs of the mold resin which are formed on the other surface side of the leadframe, resin burrs are prevented from occurring, as with the conventional method using adhesive tapes. Also, the conventionally required processes of attaching and removing the adhesive tapes are dispensed with, so that the man-hours and the material costs can be reduced. Also, semiconductor packages with resin burrs, which have conventionally been determined as defective at the appearance inspection, can be salvaged, so that improvement of the yields and reduction of the costs are expected.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1A is a sectional view showing the first process of the method of producing semiconductor packages of the present invention;

FIG. 1B is a sectional view showing the second process of the method of producing semiconductor packages of the present invention;

FIG. 1C is a sectional view showing the third process of the method of producing semiconductor packages of the present invention;

FIG. 1D is a sectional view showing the fourth process of the method of producing semiconductor packages of the present invention;

FIG. 1E is a sectional view showing the fifth process of the method of producing semiconductor packages of the present invention;

FIG. 1F is a sectional view showing the sixth process of the method of producing semiconductor packages of the present invention; and

FIG. 2 is an enlarged view of the A part in FIG. 1E.

### DETAILED DESCRIPTION OF THE INVENTION

The present invention will be explained in detail below by the embodiments shown in the attached drawings.

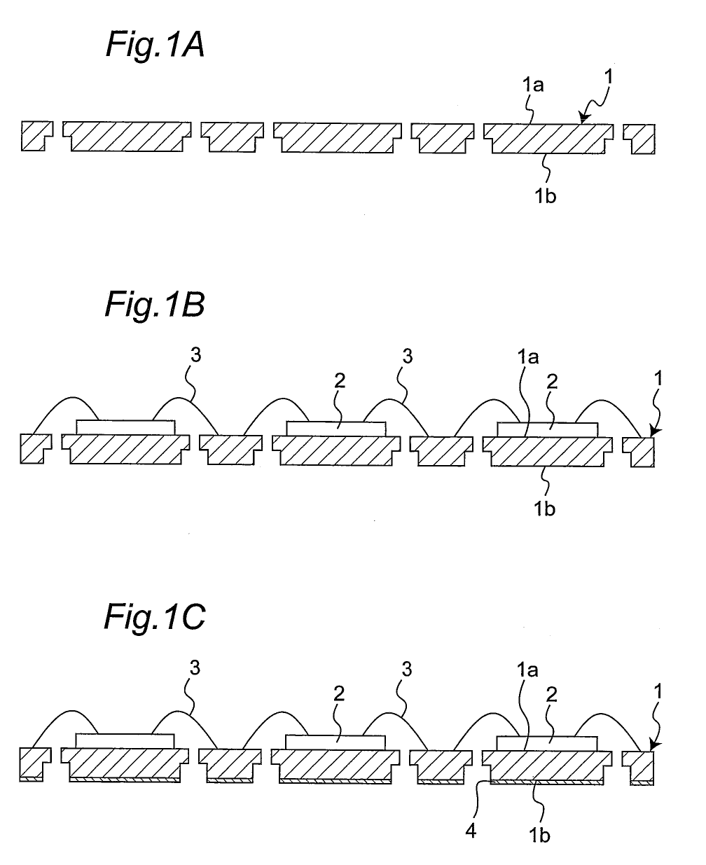

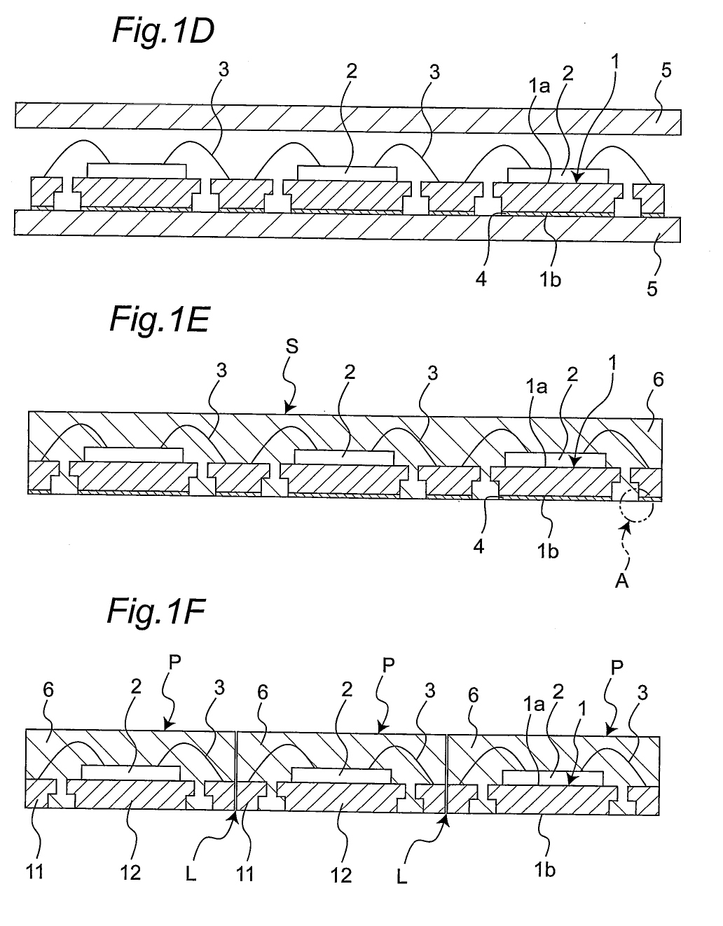

FIGS. 1A through 1F are sectional views showing production process steps according to one embodiment of the method of producing semiconductor packages of this invention. These semiconductor packages are of the QFN (Quad Flatpack Non-leaded package) type, and each package has, on its bottom side, an external electrode for electrical connection with a board (not shown).

As shown in FIG. 1A, a leadframe 1 is formed and shaped so as to have repeated same patterns. And, as shown in FIG. 1B, a plurality of semiconductor chips 2 are fixed to one 1a of two opposite surfaces of the leadframe 1 (this process is called a “die bonding process”). Then, the leadframe 1 and each semiconductor chip 2 is electrically connected to each other with wires 3 (this process is called a “wire bonding process”).

Thereafter, as shown in FIG. 1C, water-soluble masking ink 4 is applied to the other surface 1b of the leadframe 1 (this process is called an “application process”). In this application process, the masking ink 4 is applied by being sprayed directly onto the other surface 1b of leadframe 1 by the ink-jet method. The thickness of this masking ink 4 coating may preferably be in a range of from 0.5 μm to 5 μm.

And, as shown in FIG. 1D, the leadframe 1 is covered with a die 5 in the state that the masking ink 4 on the other surface 1b of the leadframe 1 touches the die 5. Then, mold resin 6 is poured into the die to seal the leadframe 1 and all of the semiconductor chips 2 with the mold resin 6, with the masking ink 4 on the other surface 1b of leadframe 1 exposed, as shown in FIG. 1E, whereby a sealed structure S is molded (this process is called a “molding process”).

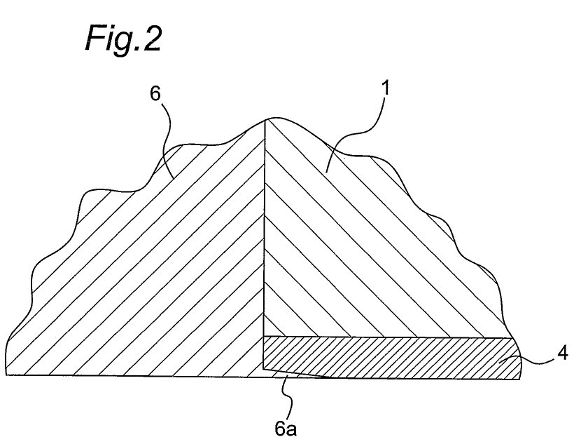

Here, an enlarged view of the part A in FIG. 1E is shown in FIG. 2. As shown in FIG. 2, the sealed structure S may be formed with burrs 6a of the mold resin 6 that are located on the masking ink 4 and on the other surface 1b side of the leadframe 1.

Thereafter, as shown in FIG. 1F, the sealed structure S is cut with the cutting water into individual semiconductor packages P. In other words, the leadframe 1 sealed with the mold resin 6 is cut along the cutting lines L every semiconductor chip 2.

At this time, while the masking ink 4 at the other surface 1b of the leadframe 1 is dissolved and removed by the cutting water, burrs 6a of the mold resin 6 on the other surface 1b side of the leadframe 1 are removed by the water pressure of the cutting water.

The semiconductor package P has a first lead 11, a second lead 12, a semiconductor chip 2, wires 3 and the mold resin 6.

The first lead 11 and the second lead 12 are formed by cutting the leadframe 1. The first lead 11 is located at an outer periphery of the bottom of the package, and the second lead 12 is placed in the center of the bottom of the package.

The semiconductor chips 2 are fixed to one surface of the second lead 12. Wires 3 electrically connect the semiconductor chip 2 and one surface of the first lead 11.

The mold resin 6 seals the first and second leads 11 and 12, the semiconductor chip 2, and the wires 3 in such a manner that the other surfaces of the first and second leads 11 and 12 are exposed to outside. The other surface of the first lead 11 and the other surface of the second lead 12 are electrically connected to a board which is not shown in the figures.

The above described production method can prevent burrs 6a of the mold resin 6, like the conventional method using adhesive tape, by applying water-soluble masking ink 4 to the other surface 1b of the leadframe 1.

Also, when the sealed structure S is cut with the cutting water into individual semiconductor packages P, the masking ink 4 on the other surface 1b of the leadframe 1 is dissolved and removed by the cutting water. Thus, the conventionally required processes of attaching and removing the adhesive tape are no more necessary.

Also, when the sealed structure S is cut with cutting water into individual semiconductor packages P, burrs 6a of the mold resin 6 formed on the other surface 1b side of the leadframe 1 are removed by the cutting water at the same time.

Thus, resin burrs 6a are prevented from occurring, as with the conventional method using adhesive tapes. Also, the conventionally required processes of attaching and removing the adhesive tapes are dispensed with, so that the man-hours and the material costs can be reduced. Also, semiconductor packages with resin burrs 6a, which have conventionally been determined as defective at the appearance inspection, can be salvaged, so that improvement of the yields and reduction of the costs are expected.

Also, in the application process, because the masking ink 4 is sprayed directly onto the other surface 1b of the leadframe 1 by the ink-jet method, the masking ink 4 can be applied easily.

It should be noted that this invention is not limited to the above-mentioned embodiment. For example, the masking ink may be applied by using rollers instead of the ink-jet method.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### REFERENCE SIGNS LIST

1: leadframe
1a: one surface
1b: the other surface
2: semiconductor chip
3: wires
4: masking ink
5: die
6: mold resin
6a: burr
11: first leads
12: second leads
L: cutting line
S: sealed structure
P: semiconductor package

1. A method of producing semiconductor packages comprising:
a die bonding process of fixing a plurality of semiconductor chips on one of two opposite surfaces of a leadframe;
a wire bonding process of electrically connecting each of the semiconductor chips to the leadframe by wires;
an application process of applying a water-soluble masking ink to the other surface of the leadframe;
a molding process of sealing the leadframe and all of the semiconductor chips with a molding resin in such a manner that the masking ink on the other surface of the leadframe is exposed, to thereby form a sealed structure;
a process of cutting the sealed structure into individual semiconductor packages by using cutting water and dissolving the masking ink on the other surface of the leadframe by the cutting water to remove the masking ink while removing, by the cutting water, burrs of the mold resin which are formed on the other surface side of the leadframe.

2. The method of producing a semiconductor package as claimed in claim 1, wherein the application process comprises spraying the masking ink directly to the other surface of the leadframe by ink-jet method.
